(19) United States
(12) Patent Application Publication
(10) Pub. No.: US 2013/0093501 A1
(43) Pub. Date: Apr. 18, 2013

(54) ELECTRICAL STIMULATION DEVICE AND ELECTRICAL STIMULATION METHOD

(71) Applicant: Hiroyuki Kajimoto, Chofu-shi (JP)

(72) Inventor: Hiroyuki Kajimoto, Chofu-shi (JP)

(73) Assignee: THE UNIVERSITY OF ELECTRO-COMMUNICATIONS, Chofu-shi, Tokyo (JP)

(21) Appl. No.: 13/702,085

(22) PCT Filed: Dec. 7, 2010
(86) PCT No.: PCT/JP2010/071880

§ 371 Date: Dec. 5, 2012

(30) Foreign Application Priority Data
Jun. 7, 2010 (JP) 2010-130532

(51) Int. Cl. H03K 17/96

(52) U.S. Cl. CPC H03K 17/96
USPC 327/517

(57) ABSTRACT

In an electrical stimulation device and an electrical stimulation method thereof, electrical stimulation can be adjusted more in real time, and stability and safety of the electrical stimulation can be more improved. An electrical stimulation device includes an electrode an electrical signal supply section, a skin impedance detection section, and an electrical signal controller. The electrical signal supply section supplies an electrical signal for generating the electrical stimulation to the electrode. During the supply of the electrical signal, the electrical signal controller acquires information associated with skin impedance through the skin impedance detection section in a cycle shorter than a supply period of the electrical signal, and adjusts the electrical signal to be supplied to the electrode in the next cycle based on the acquired information associated with skin impedance.

### CROSS REFERENCE TO RELATED APPLICATIONS

This is a U.S. national stage of application No. PCT/JP2010/071880, filed on 7 Dec. 2010. Priority under 35 U.S.C. §119(a) and 35 U.S.C. §365(b) is claimed from Japanese Application No. 2010-130532, filed 7 Jun. 2010, the disclosure of which are also incorporated herein by reference.

### TECHNICAL FIELD

The present invention relates to an electrical stimulation device and an electrical stimulation method thereof, and more particularly to an electrical stimulation device and an electrical stimulation method that provide predetermined information to a user by electrical stimulation.

### BACKGROUND ART

In recent years, various electrical stimulation devices that provide predetermined information to a user by electrical stimulation are proposed. One of such devices is an electrical tactile display. In an electrical tactile display, nerve axon connected to the receptor under the skin is driven by electrical stimulation generated from electrodes arranged in a surface of the electrical tactile display on the side touched by the skin, so as to provide the predetermined information.

The electrical tactile display has many practical advantages such as simplicity in configuration, with no mechanical drive section, with no noise problem, low power consumption and the like. However, the problem so far with the electrical tactile display is that it is difficult to stabilize the occurrence feeling caused by the electrical stimulation, and therefore the electrical tactile display is not in general use.

There are mainly two reasons that cause the unstable occurrence feeling (electrical stimulation), one reason is temporal change in sensation. The temporal change in sensation is caused due to change of condition during use caused by, for example, sweating and the like. The other reason is spatial dispersion of sensation. The spatial dispersion of sensation is caused due to change of the threshold of the electrical stimulation caused by, for example, difference of the thickness of the skin that touches the aforesaid surface of the device, local sweating and the like. The unstable electrical stimulation caused by the first reason occurs regardless the number of the electrodes, and the unstable electrical stimulation caused by the second reason occurs particularly in the case where the number of the electrodes is large.

The aforesaid two reasons will overlap in the case where the electrical tactile display is applied to a touch panel where the skin comes in touch and out of touch with the display on a frequent basis. Further, in such a use, current pathway is susceptible to change when touch state of the skin with respect to the display is switched between in-touch and out-of-touch, and therefore there is a case where the user will suffer the pain such as characteristic tingling sensation, strong uncomfortable feeling caused by electric shock, and/or the like.

To solve the aforesaid problems, various electrical stimulation methods have been proposed. For example, a technology has been proposed in which the skin impedance correlated with the aforesaid unstability of the electrical stimulation is measured, and amount of the electrical stimulation is adjusted based on the measuring result (see, for example, Non-patent document 1). FIG. 10 shows a summary of the conventional electrical stimulation method disclosed in Non-patent document 1 and the like. FIG. 10 is a waveform diagram of a stimulation pulse applied to an electrode when performing an electrical stimulation, wherein the vertical axis represents the amount of stimulation, and the horizontal axis represents the time.

In the electrical stimulation method disclosed in Non-patent document 1, before a main pulse 200 for stimulation is applied to the predetermined electrode, a pre-pulse 201 is applied to measure the skin impedance, wherein the pre-pulse 201 has a weak strength (current) so as not to cause a feeling of stimulation to the user. Further, the strength of the main pulse 200 is adjusted based on the measured skin impedance. Incidentally, in the method described in Non-patent document 1, since the measuring result of the skin impedance is fed forward to adjust the amount of the electrical stimulation, to be exact, the method does not work in real time.

### PRIOR ART DOCUMENTS

### Non-Patent Documents

Non-patent document 1: “constant energy type electric pulse stimulus information transmission device using stimulus energy as magnitude dimension parameter” Tanie Kazuo, Tachi Susumu, Japanese Society for Medical and Biological Engineering, 1980

### DISCLOSURE OF THE INVENTION

### Problems To Be Solved By the Invention

The aforesaid conventional electrical stimulation method (FIG. 10) works on the premise that the skin impedance does not rapidly change in the period from the pre-pulse 201 to the main pulse 200. However, actually it is quite possible that in such period, for example, touch strength of the skin and/or the like changes, and therefore the skin impedance changes. In such a case, since the aforesaid conventional method does not work in real time, the measuring result of the skin impedance becomes ineffective, and therefore it is difficult to stabilize the electrical stimulation.

Further, it is conventionally known that the skin impedance greatly changes according to the voltage applied to the skin. Thus, in the aforesaid conventional electrical stimulation method, if the level difference between the pre-pulse 201 and the main pulse 200 is large, it will cast doubt on the usability (credibility) of the measuring result of the skin impedance performed by the pre-pulse 201. Thus, with the conventional electrical stimulation method, although it is possible to determine whether or not the skin is in touch with the electrode, it is difficult to use the information of the skin impedance to precisely control the electrical stimulation to stabilize the electrical stimulation.

Further, in the case where the aforesaid conventional electrical stimulation method is applied to a use in which the number of the electrodes is large (for example, 100 or more), i.e., applied to a practical use, it will be difficult to completely avoid the case where the user suffers the pain such as characteristic tingling sensation, strong uncomfortable feeling caused by electric shock, and/or the like when the skin comes in touch or comes out of touch with the display. The reasons are the following.

In the electrical tactile display, when driving a large number of electrodes, typically scanning is sequentially performed while each electrode is switched between the stimulation electrode and the indifferent electrode (ground), instead of simultaneously driving all electrodes. In such a driving method, there is constantly one electrode that becomes the stimulation electrode; however, it is possible to provide a predetermined stimulation pattern (i.e., an information pattern such as a predetermined character, illustration and the like) to the user by increasing the scanning speed of the electrodes. In such a driving method, the application operation of the pre-pulse 201 and main pulse 200 shown in FIG. 10 is repeatedly performed in synchronization with the scanning of the electrodes, and the pulse group formed by the pre-pulse 201 and the main pulse 200 is congested in the time axis.

In the aforesaid driving method, when scanning and stimulation is performed in a condition where the number N of the electrodes to be driven is 50, and the refresh rate fr is 50 Hz, for example, the period T (={1/fr}/N) while one electrode is being selected (referred to as “selection period” hereinafter) will be 20 ms/50 (=400 μs). Now, if the pulse width of the main pulse 200 of the stimulation in the aforesaid conventional electrical stimulation method (see FIG. 10) is 100 μs, a quarter of the selection period T will become the application period (stimulation period) of the main pulse 200.

Thus, in the aforesaid condition, during the scanning (selection) of the electrodes, when the skin of the user comes in touch or out of touch with the electrode at a random timing, the probability that the main pulse 200 for stimulation is being flowed through the electrode will be 25%. In such a case, the possibility that the user will suffer the pain such as characteristic tingling sensation, strong uncomfortable feeling caused by electric shock, and/or the like will be 25%. Further, if the number N of the electrodes to be scanned (selected) is increased, the selection period T will decrease, and the ratio of the application period of the main pulse 200 to the selection period T will increase. As a result, the probability that the aforesaid pain caused by electrical stimulation occurs will increase. In other words, with the conventional electrical stimulation method, the larger the number of the electrodes to be scanned (selected) is, the more difficult it will be to completely ensure the safety.

Incidentally, in the conventional electrical stimulation method, since number of the electrode that causes the aforesaid pain by the electrical stimulation is one, there will be no continuous pain, and that can be considered as an advantage. However, the conventional method is not suitable for a use where the aforesaid pain caused by the electrical stimulation is required not to occur even for a moment.

The present invention is made for solving the aforesaid problems; and it is an object to, in an electrical stimulation device and an electrical stimulation method, adjust the electrical stimulation more in real time, so as to more improve stability and safety of the electrical stimulation (occurrence feeling).

### Means For Solving the Problems

To solve the aforesaid problems, an electrical stimulation device according to an aspect of the present invention includes: an electrode, a electrical signal supply section, a skin impedance detection section, and a electrical signal controller, wherein the electrode is adapted to provide electrical stimulation to a user, the electrical signal supply section is adapted to supply a electrical signal for generating the electrical stimulation to the electrode, the skin impedance detection section is adapted to detect information associated with skin impedance of the user, and the electrical signal controller is adapted to acquire, during the supply of the electrical signal, the information associated with the skin impedance through the skin impedance detection section in a cycle shorter than a supply period of the electrical signal, and adjust the electrical signal to be supplied to the electrode in the next cycle based on the acquired information associated with the skin impedance.

Further, the electrical stimulation method according to another aspect of the present invention includes the steps of: supplying a electrical signal to a predetermined electrode; acquiring, during the supply of the electrical signal, information associated with skin impedance of a user in a cycle shorter than one supply period of the electrical signal of the predetermined electrode; and adjusting the electrical signal of the next cycle based on the acquired information associated with the skin impedance.

Incidentally, the term “supply period of the electrical signal (stimulation period)” in this description means that a period in which a current for stimulation (i.e., a stimulation current) is continuously applied when performing one electrical stimulation on a predetermined electrode. Further, the term “information associated with skin impedance” in this description does not only include the skin impedance itself, but also include any parameter associated with the skin impedance such as, for example, the voltage and current applied to the skin of the user during the electrical stimulation.

As described above, in the electrical stimulation device and the electrical stimulation method thereof according to the present invention, the information associated with the skin impedance is acquired in a cycle shorter than one stimulation period of the predetermined electrode, and the stimulation current of the next cycle is adjusted based on the acquired information. In other words, in the present invention, feedback processing for detecting the information associated with the skin impedance and adjusting the amount of stimulation is performed for a plurality of times during one stimulation period of the predetermined electrode. Thus, in the present invention, it is possible to substantially unite a measurement phase of the information associated with the skin impedance and an adjustment phase of the stimulation, and therefore the feedback control of the amount of stimulation based on the information associated with the skin impedance can be performed more in real time.

### Advantages of the Invention

As described above, in the present invention, since the feedback control of the amount of stimulation based on the information associated with the skin impedance can be performed more in real time, it is possible to respond to rapid change in skin impedance during the stimulation. Thus, according to the present invention, with the electrical stimulation device and the electrical stimulation method thereof, it is possible to further improve stability and safety of the electrical stimulation (occurrence feeling).

### BRIEF DESCRIPTION OF DRAWINGS

FIG. 1 is a block diagram briefly showing the configuration of an electrical stimulation device according to an embodiment of the present invention;

FIG. 2 is a diagram showing a configuration example of a skin impedance detection section of the electrical stimulation device according to the aforesaid embodiment of the present invention;

FIG. 3 is a diagram showing the inner configuration of both a switch group and a touch panel of the electrical stimulation device according to the aforesaid embodiment of the present invention;

FIGS. 4A and 4B are views for explaining the operation of a changing-over switch;

FIG. 5 is a view showing an example of scanning electrodes;

FIG. 6 is a view for explaining the principle of adjusting the amount of stimulation;

FIG. 7 is a flowchart showing the steps of adjusting the amount of stimulation of the electrical stimulation device according to the aforesaid embodiment of the present invention;

FIG. 8 is a graph showing an adjustment curve group of stimulation intensity used to perform volume adjusting function of an electrical stimulation device according to a modification 1;

FIG. 9 is a view for explaining a method for adjusting the amount of stimulation in a modification 2; and

FIG. 10 is a view for explaining an electrical stimulation method according to a conventional art.

### BEST MODES FOR CARRYING OUT THE INVENTION

An example of an electrical stimulation device according to an embodiment of the present invention and an electrical stimulation method thereof will be described in the following order with reference to the attached drawings. Note that the present invention is not limited to this example.
1. Basic configuration of electrical stimulation device
2. Method for adjusting amount of stimulation
3. Various modifications and applications

### 1. Basic Configuration of Electrical Stimulation Device

### [Configuration of Electrical Stimulation Device]

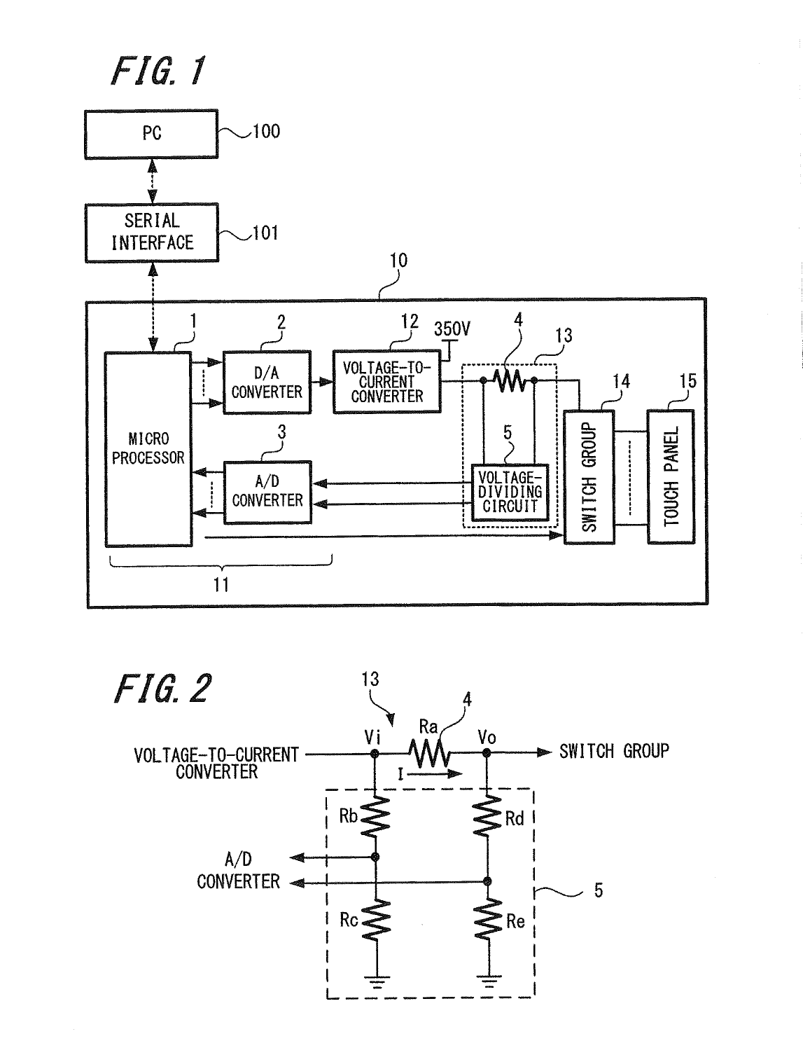

FIG. 1 is a block diagram showing the configuration of an electrical stimulation device according to an embodiment of the present invention. Incidentally, FIG. 1 shows a system established for verifying the performance of an electrical stimulation device 10 of the present embodiment.

The validation system of the present embodiment mainly includes the electrical stimulation device 10, a personal computer 100, and a serial interface 101.

In the validation system shown in FIG. 1, a signal of a predetermined stimulation pattern (i.e., an information pattern such as a predetermined character, illustration and the like) to be provided on a touch panel (which is to be described later) of the electrical stimulation device 10 is generated by the personal computer 100. Further, the personal computer 100 transmits the generated signal of the predetermined stimulation pattern to the electrical stimulation device 10 by high-speed serial communication through the serial interface 101. The electrical stimulation device 10 controls electrical stimulation so that the received information of the stimulation pattern is provided on the touch panel.

The electrical stimulation device 10 includes a stimulation pulse controller 11, a voltage-to-current converter 12 (i.e., a stimulation current supply section), a skin impedance detection section 13, a switch group 14 (switches), and a touch panel 15.

The stimulation pulse controller 11 has a microprocessor 1, a digital-to-analog converter 12 (referred to as a “D/A converter 2” hereinafter), and an analog-to-digital converter 3 (referred to as an “A/D converter 3” hereinafter).

The microprocessor 1 functions both as an arithmetic processing unit and as a control unit, and is adapted to control the operation of each section of the electrical stimulation device 10 when adjusting the amount of stimulation (which is to be described later). Further, the microprocessor 1 has a storage (not shown). Various kinds of judgment data to be used when adjusting the amount of stimulation are stored in the storage, wherein examples of the judgment data include correlation data between the threshold of the pulse width of a stimulation pulse and the skin impedance.

Incidentally, in the present embodiment, a microprocessor having an operating frequency of 25 MHz is used as the microprocessor 1. However, any microprocessor can be used as the microprocessor 1 as long as it has high-speed performance. When considering possible applications of the electrical stimulation device 10 to various usages, it is preferred that the microprocessor 1 is selected considering, for example, the availability of the microprocessor 1, the variety of the input-output interface, and the like.

The D/A converter 2 (the digital-to-analog converter) converts a digital signal (i.e., a stimulation voltage signal) parallel-outputted from the microprocessor 1 into an analog signal. Further, the D/A converter 2 outputs the converted analog signal to the voltage-to-current converter 12.

Incidentally, a D/A converter having a bit number of 12-bit, a sampling rate of 1 Msps, and a settling time of 1 μs is used as the D/A converter 2. The interface of the D/A converter 2 on the side connected to the microprocessor 1 (i.e., the signal input side) is a parallel interface.

The both input terminals of the A/D converter 3 (the analog-to-digital converter) are respectively connected to the both ends of a resistor 4 through a voltage-dividing circuit 5 (which is to be described later) arranged in the skin impedance detection section 13. The voltage signal between the both ends of the resistor 4 is inputted to the A/D converter 3, and the A/D converter 3 converts the inputted signal (which is an analog signal) into a digital signal. Further, the A/D converter 3 parallel-outputs the converted digital signal to the microprocessor 1.

Incidentally, an A/D converter having a bit number of 12-bit and a sampling rate of 1.25 Msps is used as the A/D converter 3. By using the A/D converter 3 having such performance, it is possible to make the sampling interval (1 μs or less) of the A/D converter 3 sufficiently smaller than electrical time constant of the skin, and therefore it is possible to perform substantially simultaneous sampling. Further, the interface of the A/D converter 3 on the side connected to the microprocessor 1 (i.e., the signal input side) is a parallel interface.

Conventional microprocessors also include the one that has a D/A converter and an A/D converter; however, as described above, in the present embodiment, the D/A converter 2 and the A/D converter 3, which each have a parallel interface, are provided separately from the microprocessor 1. This configuration is used for the following reasons. As to be described later, in the electrical stimulation device 10 of the present embodiment, the skin impedance is measured, and the measuring result is fed back to adjust the amount of stimulation, wherein the period of the feedback processing necessary for the present embodiment is several ps or less. However, as it stands now, it is difficult for the D/A converter and A/D converter built in the microprocessor to perform such high-speed processing, and therefore such microprocessor is unsuitable to be applied to the electrical stimulation device.

Further, conventionally, there is a D/A converter and an A/D converter, which each have a serial interface, capable of performing high-speed operation. However, in order to achieve the aforesaid high-speed feedback processing, it is necessary to reduce the communication time between the microprocessor 1 and the D/A converter and A/D converter. Thus, in the present embodiment, the D/A converter 2 and the A/D converter 3 each with a parallel interface are used, wherein the D/A converter 2 and A/D converter 3 can more greatly reduce the communication time than the D/A converter and A/D converter each with a serial interface.

The voltage-to-current converter 12 converts the voltage signal outputted from the D/A converter 2, which has been converted into the analog signal by the D/A converter 2, into a current signal (i.e., a stimulation current). Further, the voltage-to-current converter 12 supplies, through the skin impedance detection section 13 and the switch group 14, the converted current signal to a selected predetermined electrode in the touch panel 15. In other words, in the electrical stimulation device 10 of the present embodiment, the amount of the electrical stimulation is adjusted by performing current control.

The skin impedance detection section 13 has the resistor 4 and the voltage-dividing circuit 5. The resistor 4 and the voltage-dividing circuit 5 are provided to measure the impedance of the skin (the skin impedance Z) coming in touch with the electrodes in the touch panel 15.

FIG. 2 shows the inner configuration of the voltage-dividing circuit 5 of the present embodiment, and connection relation between the resistor 4 and the voltage-dividing circuit 5. The voltage-dividing circuit 5 is a circuit for accurately measuring the voltage between the both ends (i.e., input and output terminals) of the resistor 4, and includes four voltage-dividing resistors Rb, Rc, Rd, Re. Incidentally, in the present embodiment, since a high voltage of about 350V, for example, is used, the voltage-dividing circuit 5 shown in FIG. 2 is provided.

One end (i.e., the input terminal) of the resistor 4 is connected to the output terminal of the voltage-to-current converter 12, and the other end (i.e., the output terminal) of the resistor 4 is connected to the input terminal of the switch group 14. Further, a series resistor consisting of the voltage-dividing resistors Rb and Rc is connected to the one end of the resistor 4, and a series resistor consisting of the voltage-dividing resistors Rd and Re is connected to the other end of the resistor 4. Further, the terminal of the series resistor consisting of the voltage-dividing resistors Rb and Rc on the side opposite to the side of the resistor 4 is grounded, and the connecting point of the voltage-dividing resistor Rb with the voltage-dividing resistor Rc is connected to the A/D converter 3. Further, the terminal of the series resistor consisting of the voltage-dividing resistors Rd and Re on the side opposite to the side of the resistor 4 is grounded, and the connecting point of the voltage-dividing resistor Rd with the voltage-dividing resistor Re is connected to the A/D converter 3.

In order to measure the skin impedance Z, it is necessary to measure a voltage Vo applied to the skin and a current I flowing through the skin. The voltage Vo applied to the skin can be obtained by detecting the voltage of one end of the resistor 4 (whose resistance value is Ra) on the side of the switch group 14. On the other hand, the current I flowing through the skin can be calculated based on the potential difference (Vo−Vi) between the both ends of the resistor 4 (i.e., I=(Vo−Vi)/Ra).

Incidentally, the potential difference (Vo−Vi) between the both ends of the resistor 4 is very small, and therefore in order to accurately measure the current I flowing through the skin, it is preferred that precision resistors whose error is about 0.1% are used as the voltage-dividing resistors Rb, Rc, Rd, Re of the voltage-dividing circuit 5. In the electrical stimulation device 10 of the present embodiment, by using such precision resistors as the voltage-dividing resistors Rb, Rc, Rd, and Re, and by employing the A/D converter 3 of 12-bit, the dynamic range of the current measurement can be kept at 9-bit.

Incidentally, as to be described later, if the stimulation current used when measuring the skin impedance Z is a constant value (like the case of the present embodiment), it will be not necessary to measure the current I flowing through the resistor 4. Thus, in such a case, it is not necessary to use the aforesaid precision resistors with small error in resistance as the voltage-dividing resistors Rb, Rc, Rd, and Re in the voltage-dividing circuit 5.

Further, in the present embodiment, due to the construction of the changing-over switches 20 (which are to be described later) in the switch group 14, it is not possible to measure the current on the ground side (downstream side) of the skin, and therefore the resistor 4 and the voltage-dividing circuit 5 are arranged on the high-voltage side (upstream side) of the skin to measure the current.

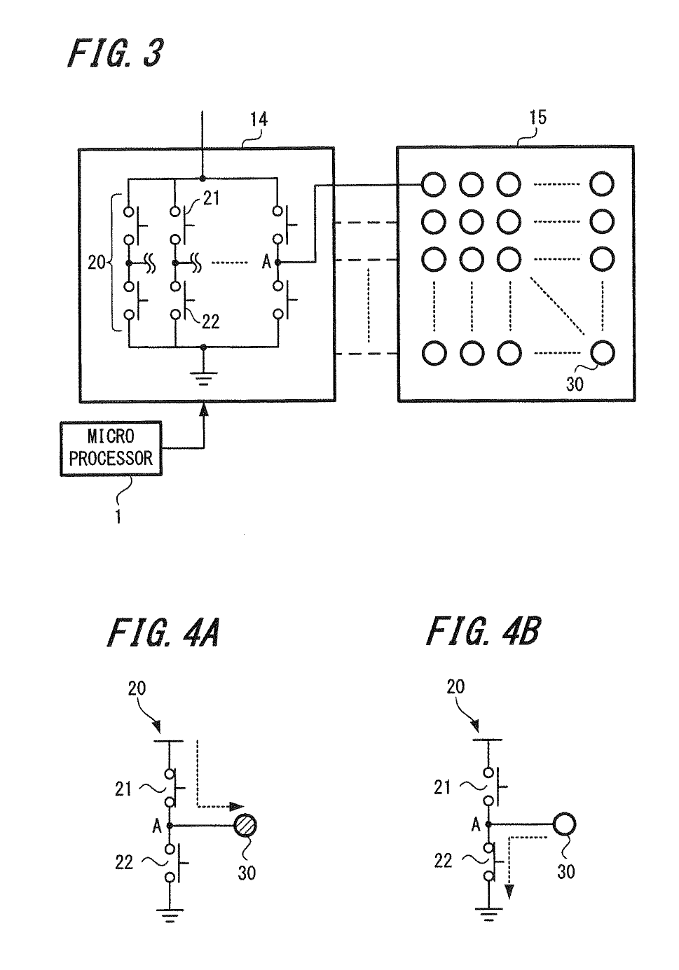

Next, the configuration of both the switch group 14 and the touch panel 15 of the present embodiment will be described in more detail with reference to FIG. 3. FIG. 3 is a diagram showing the inner configuration of both the switch group 14 and the touch panel 15.

The switch group 14 includes a plurality of changing-over switches 20. Each changing-over switch 20 is configured by connecting a first switch 21 and a second switch 22 in series. Incidentally, in the present embodiment, the number of the changing-over switches 20 is the same as the number of electrodes 30 (which are to be described later) in the touch panel 15.

The plurality of changing-over switches 20 are connected in parallel with each other. One end of each changing-over switch 20 is connected to the resistor 4, and the other end of each changing-over switch 20 is grounded. The connecting point A of the first switch 21 with the second switch 22 in each changing-over switch 20 is connected to a corresponding electrode 30 in the touch panel 15.

The ON/OFF operation of both the first switch 21 and second switch 22 of each changing-over switch 20 is controlled by the microprocessor 1. The ON/OFF operation of both the first switch 21 and the second switch 22 will be briefly described with reference to FIGS. 4A and 4B. Incidentally, FIG. 4A shows an ON/OFF state of the first switch 21 and the second switch 22 when the stimulation current is supplied to the electrode 30, and FIG. 4B shows an ON/OFF state of the first switch 21 and the second switch 22 when the stimulation current is not supplied to the electrode 30.

In the electrical stimulation device 10 of the present embodiment, when an electrical stimulation is applied to the user, the one electrode 30 from a plurality of electrodes 30 of the touch panel 15 is scanned and selected in a predetermined order based on the signal of the predetermined stimulation pattern inputted from the personal computer 100, and the stimulation current is supplied to the selected electrode 30. Thus, as shown in FIG. 4A, when the electrode 30 is selected, the microprocessor 1 performs control so that the first switch 21 is in ON state, and the second switch 22 is in OFF state.

On the other hand, when scanning the electrodes 30, the electrode 30 not selected is grounded. Thus, as shown in FIG. 4B, when the electrode 30 is not selected, the microprocessor 1 performs control so that the first switch 21 is in OFF state, and the second switch 22 is in ON state.

The touch panel 15 includes a plurality of electrodes 30. The plurality of electrodes 30 are arranged in a two-dimensional array. Incidentally, the number and arrangement of the electrodes 30 can be suitably set according to, for example, intended use and/or the like. Each electrode 30 can be formed of any material as long as such material is an electrically-conductive material, and the material of the electrode 30 can be suitably selected according to, for example, intended use and/or the like. Further, as shown in FIG. 3, although the shape of the surface of the electrode 30 on the side in touch with the skin of the user is circle, the shape of the surface of the electrode may be suitably designed according to, for example, intended use and/or the like.

FIG. 5 shows an example of scanning the electrodes 30 in the touch panel 15. Incidentally, in FIG. 5, the electrode 30 to which the stimulation current is supplied (i.e., the selected electrode 30) is indicated as a hatched circle, and the electrodes 30 to which the stimulation current is not supplied (i.e., the electrodes 30 not selected) is indicated as void circles.

In the example shown in FIG. 5, first, the microprocessor 1 selects a predetermined row in the electrode group. Next, in the selected row, the microprocessor 1 sequentially performs selection from the electrode 30 located on one end of the plural electrodes 30 to the electrode 30 located on the other end of the plural electrodes 30 (in the example shown in FIG. 5, the microprocessor 1 sequentially performs selection in a direction from left to right). As described above with reference to FIG. 4A and 4B, such selection is performed by performing ON/OFF operation of the changing-over switches 20 under control of the microprocessor 1. Incidentally, the scanning pattern of the electrodes 30 is not limited to the example shown in FIG. 5, but may be suitably set according to, for example, intended use, the stimulation pattern inputted from the personal computer 100, and/or the like.

### 2. Method For Adjusting Amount of Stimulation

### [Summary of Adjusting Method]

As described above, in the electrical stimulation device 10 of the present embodiment, not only the microprocessor 1 capable of performing high-speed processing is employed, but also the D/A converter 2 and A/D converter 3 each with a parallel interface are employed in order to more greatly reduce the data communication time between the microprocessor 1 and the D/A converter 2 and A/D converter 3. Various preliminary experiments are performed with respect to the electrical stimulation device 10 having the aforesaid configuration by using the validation system shown in FIG. 1, and it has been confirmed based on the results of the preliminary experiments that, with the electrical stimulation device 10 of the present embodiment, it is possible to perform the feedback processing with a processing time of about several μs. Incidentally, the description of the preliminary experiments is omitted herein.

In other words, it has been confirmed that, with the electrical stimulation device 10 of the present embodiment, it is possible to perform several times to a couple dozens times of feedback processing within one stimulation period (about several hundred μs) of one electrode 30. Further, it is known from the preliminary experiments with respect to the electrical stimulation device 10 of the present embodiment that, with the electrical stimulation device 10 of the present embodiment, it is possible to perform judgment processing between in-touch and out-of-touch of the skin with a very short period (about several us) from the time when the stimulation is started.

In the present embodiment, a feedback loop of measurement processing of the skin impedance Z and adjustment processing of the amount of stimulation based on the measuring result is performed for several times to a couple dozens times within one stimulation period of one electrode 30. Incidentally, the period (about several us) of the feedback processing performed in the present embodiment is sufficiently shorter than the time for a user to feel the electrical stimulation. Thus, in the present embodiment, it is possible to substantially unite a measurement phase of the skin impedance Z and an adjustment phase of the stimulation in one stimulation period. In other words, in the present embodiment, the feedback control of the amount of stimulation based on information associated with the skin impedance Z can be performed more in real time.

Further, in the present embodiment, correlation data between the pulse width (threshold ΔTth) of the stimulation pulse when the user starts to feel the electrical stimulation and the skin impedance Z (the information associated with the skin impedance Z) is used when performing the feedback control of the amount of stimulation. It is conventionally known that there is a strong correlation between the threshold ΔTth of the pulse width of the stimulation pulse and the skin impedance Z. To be specific, the relation between the both is: the larger the skin impedance Z is, the smaller the threshold ΔTth of the pulse width of the stimulation pulse will become.

In the present embodiment, the correlation data (referred to as “adjustment data” hereinafter) between the skin impedance Z and the threshold ΔTth of the pulse width of the stimulation pulse is previously obtained by using a predetermined stimulation current. Further, when performing the feedback control of the amount of stimulation, the amount of stimulation is adjusted based on the adjustment data.

Incidentally, as to be described later, in the present embodiment, when measuring the skin impedance Z, since the value of the stimulation current is constant, the voltage Vo of the end of the resistor 4 (see FIG. 2) on the side of the switch group 14 (i.e., the voltage applied to the skin) is a parameter equivalent to the skin impedance Z. Thus, in such a case, instead of the correlation data between the skin impedance Z and the threshold ΔTth of the pulse width of the stimulation pulse, correlation data between the voltage Vo of the end of the resistor 4 on the side of the switch group 14 (the information associated with the skin impedance Z) and the threshold ΔTth of the pulse width of the stimulation pulse may also be used as the adjustment data.

### [Principle of Adjusting Amount of Stimulation]

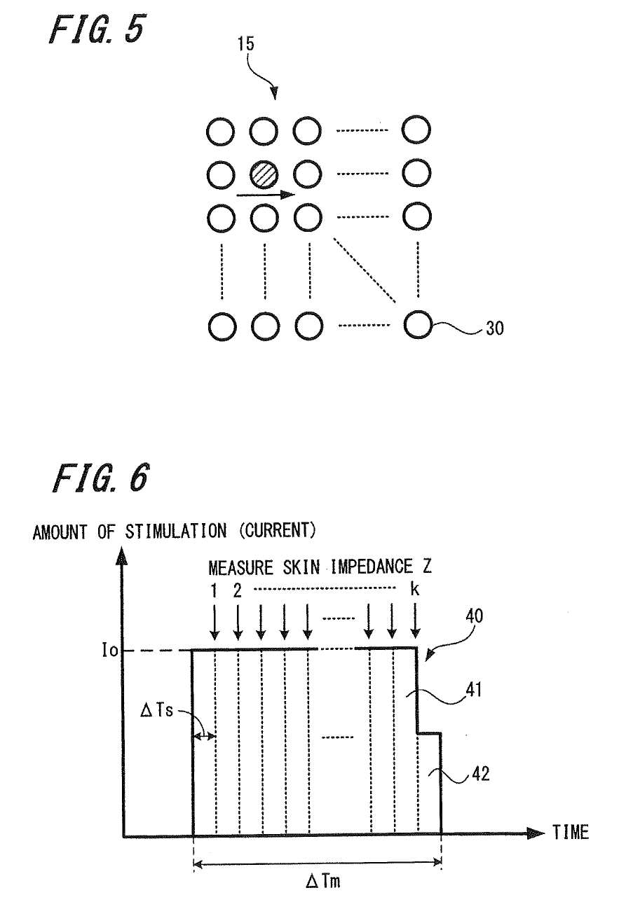

Next, principle of the method for adjusting the amount of stimulation of the electrical stimulation device 10 of the present embodiment will be described in more detail with reference to FIG. 6. FIG. 6 is a waveform diagram of a stimulation pulse 40 applied to a predetermined electrode 30 over one stimulation period (i.e., one selection period), wherein the horizontal axis represents the time, and the vertical axis represents the amount of stimulation (the current value).

In the present embodiment, first, a stimulation current of a predetermined current value Io (for example, about 5 mA) is supplied to the electrode 30 selected by the changing-over switches 20. Thereafter, the skin impedance Z is measured after a predetermined time (i.e., a measurement cycle ΔTs of the skin impedance Z) has elapsed since the start of the stimulation. Incidentally, the measurement cycle ΔTs (cycle) of the skin impedance Z is a period (for example, about several us) sufficiently shorter than one stimulation period ΔTm (or selection period) of the electrode 30, and the current value Io of the stimulation current in the measurement cycle ΔTs is constant.

Thereafter, a threshold ΔTth of the pulse width of the stimulation pulse 40 is obtained from the adjustment data based on the measured skin impedance Z, and it is determined whether or not the stimulation pulse 40 is to be stopped based on the obtained threshold ΔTth. At this time, the pulse width of the stimulation pulse 40 in the case where the stimulation current has been further flowed for the measurement cycle ΔTs from the time when the skin impedance Z is measured (such pulse width will be referred to as “final pulse width” hereinafter) is compared with the threshold ΔTth of the pulse width obtained from the adjustment data to thereby determine whether or not the stimulation pulse 40 is to be stopped.

To be specific, if the threshold ΔTth of the pulse width of the stimulation pulse 40 calculated at the k-th impedance measurement, for example, is smaller than the final pulse width ({k+1}ΔTs) of the stimulation pulse 40 (i.e., ΔTth<{k+1}ΔTs), then it is determined that the stimulation pulse 40 is to be stopped.

In such a case, if the threshold ΔTth of the pulse width calculated at the k-th impedance measurement, for example, is equal to kΔTs (i.e., ΔTth=kΔTs), then the stimulation current is to be stopped at the point of the k-th impedance measurement.

Further, if the threshold ΔTth of the pulse width calculated at the k-th impedance measurement, for example, is larger than kΔTs but smaller than {k+1}ΔTs (i.e., kΔTs<ΔTth<{k+1}ΔTs), then the current value of the stimulation current to be supplied in the next measurement cycle ΔTs is reduced, and the stimulation current is stopped after the next measurement cycle ΔTs has elapsed. At this time, the current value of the stimulation current of the final current-flowing period is adjusted so that the total amount of stimulation (amount of current) provided by the stimulation pulse 40 is substantially equal to the total amount of stimulation when the stimulation current of current value Io is flowed in the threshold ΔTth.

For example, if the threshold ΔTth of the pulse width of the stimulation pulse 40 calculated at the final (the k-th) impedance measurement is equal to (k+0.3)ΔTs, the value of the stimulation current in the final current-flowing period will be set to 0.3 Io. Note that, since the measurement cycle ΔTs of the skin impedance Z is a parameter determined within the limitations of the hardware of the system, the threshold ΔTth of the pulse width of the stimulation pulse 40 calculated based on the measured skin impedance Z may not necessarily be the integral multiple of the measurement cycle ΔTs.

On the other hand, if the threshold ΔTth of the pulse width calculated at the k-th impedance measurement, for example, is equal to or larger than the final pulse width of the stimulation pulse 40 (i.e., ΔTth≧{k+1}1ΔTs), the stimulation current of the current value Io will also be supplied to the electrode 30 in the next measurement cycle ΔTs (current-flowing period).

In the present embodiment, the aforesaid measurement of the skin impedance Z and determination of whether or not the stimulation pulse 40 is to be stopped are repeatedly performed for each measurement cycle ΔTs. Thus, in the present embodiment, as shown in FIG. 6, the stimulation pulse 40 applied to the electrode 30 is a pulse obtained by continuously applying a sub-pulse 41 for a predetermined number of times, and then applying an adjusting sub-pulse 42 having a reduced stimulation current in the final current-flowing period (ΔTs), wherein the sub-pulse 41 has a pulse width corresponding to the measurement cycle ΔTs of the skin impedance Z. In other words, in the present embodiment, not only the pulse width ΔTm of the stimulation pulse 40 applied to the predetermined electrode 30 is controlled, but also the pulse shape of the stimulation pulse 40 is controlled based on the measured skin impedance Z.

Incidentally, the current value Io (intensity) of the stimulation current of the sub-pulse 41 is suitably set according to, for example, the stimulation intensity required by the user (the skin impedance), the pulse width (ΔTs) of the sub-pulse 41, and/or the like. Further, the measurement cycle ΔTs of the skin impedance Z (i.e., the pulse width of the sub-pulse 41) is suitably set according to, for example, the stimulation intensity required by the user, one selection period of the electrode 30, and/or the like.

### [Operation of Adjusting Amount of Stimulation]

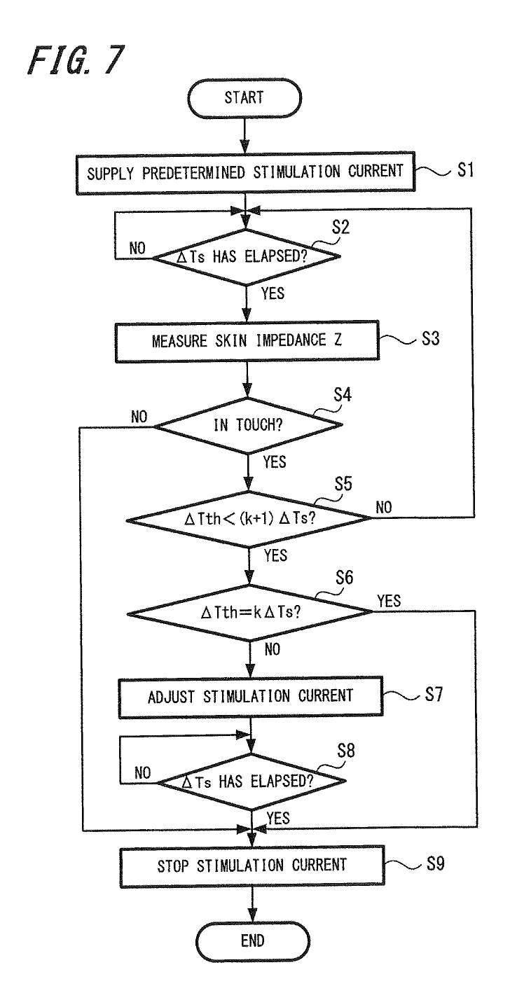

Next, concrete processing steps for adjusting the amount of stimulation in the electrical stimulation device 10 of the present embodiment will be described below with reference to FIG. 7. FIG. 7 is a flowchart showing the concrete processing steps for adjusting the amount of stimulation in the present embodiment.

First, the microprocessor 1 controls the switch group 14 to select a predetermined electrode 30. Next, the microprocessor 1 supplies the stimulation current of the predetermined current value Io to the selected electrode 30 through the D/A converter 2, the voltage-to-current converter 12, the resistor 4 and the switch group 14 (Step S1). At this time, the microprocessor 1 counts the time elapsed since the current has been flowed.

Thereafter, the microprocessor 1 determines whether or not the time elapsed since the current has been flowed or the time elapsed after the last measurement of the skin impedance Z (Step S3 to be described later) has exceeded the preset measurement cycle ΔTs of the skin impedance Z (Step S2).

In Step S2, if the elapsed time has not reached the measurement cycle ΔTs, the determination result in Step S2 will be “NO”. In such a case, the processing of Step S2 is repeatedly performed in a state where the stimulation current of the current value Io is supplied, until the elapsed time has reached the measurement cycle ΔTs.

On the other hand, in Step S2, if the elapsed time has reached the measurement cycle ΔTs, the determination result of step S2 will be “YES”. In such a case, the microprocessor 1 detects the voltage between the both ends of the resistor 4 through the voltage-dividing circuit 5 and the A/D converter 3, and calculates the skin impedance Z based on the detection result (Step S3). Incidentally, if the value of the stimulation current used when measuring the skin impedance Z is a constant value (like the case of the present embodiment), it will be only needed to detect the voltage Vo of the end of the resistor 4 on the side of the switch group 14. Further, if the determination result in Step S2 is “YES”, the microprocessor 1 will reset the count of the elapsed time to recount the elapsed time.

Thereafter, based on the skin impedance Z measured (calculated) in Step S3, the microprocessor 1 determines whether or not the skin is in touch with the currently selected electrode 30 (Step S4). Such determination is performed by, for example, comparing a predetermined threshold of the skin impedance Z with the skin impedance Z measured in Step S3, wherein the predetermined threshold is previously set (stored) in the microprocessor 1 and adapted for determining whether the skin is in touch or out of touch with the electrode 30. If the measured skin impedance Z is larger than the predetermined threshold, the microprocessor 1 will determine that the skin is out of touch with the currently selected electrode 30.

In Step S4, if the microprocessor 1 determines that the skin is out of touch with the currently selected electrode 30, the determination result in step S4 will be “NO”. In such a case, the supply of the stimulation current will be stopped (Step S9), and the control of the current stimulation will be terminated.

On the other hand, in Step S4, if the microprocessor 1 determines that the skin is in touch with the currently selected electrode 30, the determination result in step S4 will be “YES”. In such a case, based on the measured skin impedance Z, the microprocessor 1 obtains the threshold ΔTth of the pulse width of the stimulation pulse from the adjustment data stored in the microprocessor 1. Further, the microprocessor 1 calculates the final pulse width ({k+1}ΔTs, where k=1, 2, . . . ) of the stimulation pulse 40. Further, the microprocessor 1 determines whether or not the threshold ΔTth of the pulse width of the stimulation pulse is smaller than the final pulse width ({k+1}ΔTs) of the stimulation pulse 40 (Step S5).

In Step S5, if the threshold ΔTth of the pulse width is equal to or larger than the final pulse width of the stimulation pulse 40 (i.e., ΔTth≧{k+1}1ΔTs), the determination result of Step S5 will be “NO”. In such a case, the process returns to Step S2 to repeatedly perform the processing after Step S2 while the value of the stimulation current is maintained at the current value Io.

On the other hand, in Step S5, if the threshold ΔTth of the pulse width is smaller than the final pulse width of the stimulation pulse 40 (i.e., ΔTth<{k+1}ΔTs), the determination result of step S5 will be “YES”. In such a case, the microprocessor 1 determines whether or not the threshold ΔTth of the pulse width is equal to the current pulse width (kΔTs) of the stimulation pulse 40 (Step S6).

In Step S6, if the threshold ΔTth of the pulse width is equal to the current pulse width of the stimulation pulse 40 (i.e., ΔTth=kΔTs), the determination result of step S6 will be “YES”. In such a case, the supply of the stimulation current will be stopped (Step S9), and the control of the current stimulation will be terminated.

On the other hand, in Step S6, if the threshold ΔTth of the pulse width is not equal to the current pulse width of the stimulation pulse 40 (i.e., kΔTs<ΔTth<{k+1}ΔTs), the determination result of step S6 will be “NO”. In such a case, if the stimulation current of the current value Io keeps flowing until the next impedance measurement, the stimulation will be excessive. Thus, if the determination result of step S is “NO”, the microprocessor 1 will reduce (adjust) the current value of the stimulation current according to, for example, the aforesaid principle of adjusting amount of stimulation (Step S7).

Thereafter, the microprocessor 1 determines whether or not the time elapsed after the measurement of the skin impedance Z (Step S3) has exceeded the preset measurement cycle ΔTs (i.e., the pulse width of the sub-pulse 41) of the skin impedance Z (Step S8). In Step S8, if the elapsed time has not reached the measurement cycle ΔTs, the determination result of step S8 will be “NO”; in such case, the processing of Step S8 is repeatedly performed in a state where the adjusted stimulation current is supplied, until the elapsed time has reached the measurement cycle ΔTs.

On the other hand, in Step S8, if the elapsed time has reached the measurement cycle ΔTs, the determination result in step S8 will be “YES”. In such a case, the microprocessor 1 stops supplying the stimulation current (Step S9), and terminates the control of the current stimulation on the selected electrode 30.

In the present embodiment, the amount of stimulation is adjusted with respect to the selected electrode 30 in the aforesaid manner. Actually, the inventor of the present application has performed a verification experiment of the electrical stimulation on a plurality of subjects by using the aforesaid electrical stimulation method. Incidentally, in the experiment, the measurement cycle ΔTs (the pulse width of the sub-pulse 41) of the skin impedance Z and the current value Io of the stimulation current are respectively set to 1.45 μs and 5 mA. As a result, reports from all subjects show that stable stimulation was obtained.

In other words, it is known that, with the electrical stimulation device 10 of the present embodiment and the electrical stimulation method using the electrical stimulation device 10, it is possible to provide the user with optimum electrical stimulation (occurrence feeling) more stably. Further, as described above, in the present embodiment, since the feedback control of the amount of stimulation based on the information associated with the skin impedance Z can be performed more in real time, it is possible to respond to rapid change in skin impedance during the stimulation. Thus, with the present embodiment, it is possible to further improve stability and safety of the electrical stimulation.

### 3. Various Modifications And Applications

### [Modification 1]

The electrical stimulation device 10 of the aforesaid embodiment is described based on an example in which one piece of adjustment data, which shows correlation between the threshold ΔTth of the pulse width of the stimulation pulse (i.e., the pulse width when the user starts to feel the electrical stimulation) and the skin impedance Z, is prepared; however, the present invention is not limited to this example.

There is a possible configuration in which a plurality of pieces of adjustment data are respectively prepared for a plurality of different stimulation intensities, wherein each piece of adjustment data shows correlation between the threshold ΔTth of the pulse width of the stimulation pulse and the skin impedance Z, and the user can select, from the plurality of pieces of adjustment data, a piece of adjustment data corresponding to his (or her) favorite stimulation intensity. In other words, the electrical stimulation device 10 of the aforesaid embodiment may further be provided with a stimulation intensity changing function (referred to as a “volume adjusting function” hereinafter).

In order to provide such a stimulation intensity volume adjusting function to the electrical stimulation device 10 of the aforesaid embodiment, a plurality of pieces of adjustment data respectively corresponding to a plurality of different stimulation intensities may be previously stored in the microprocessor 1, for example.

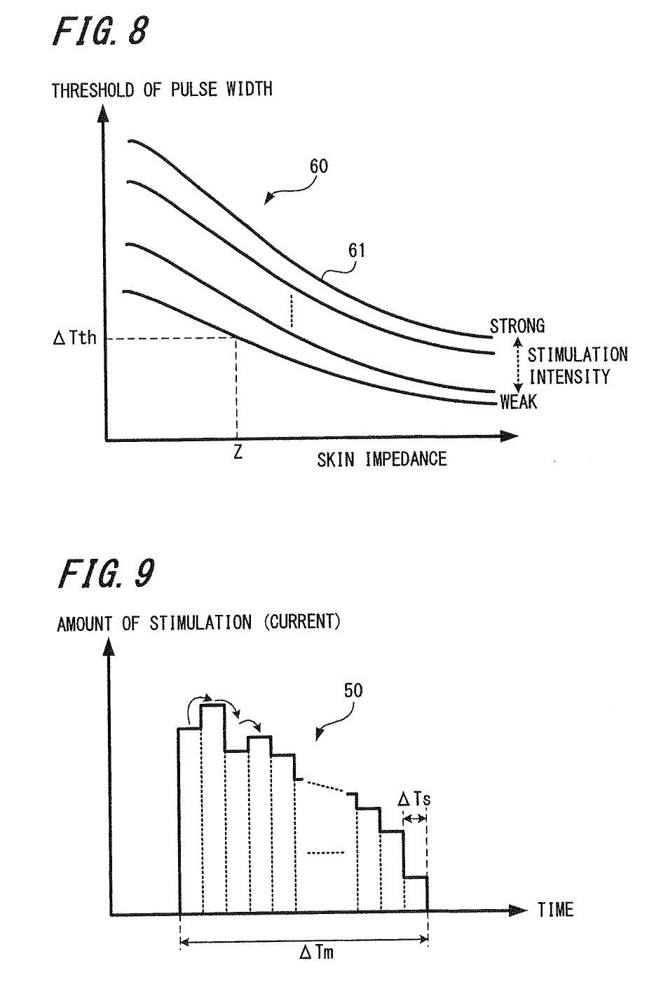

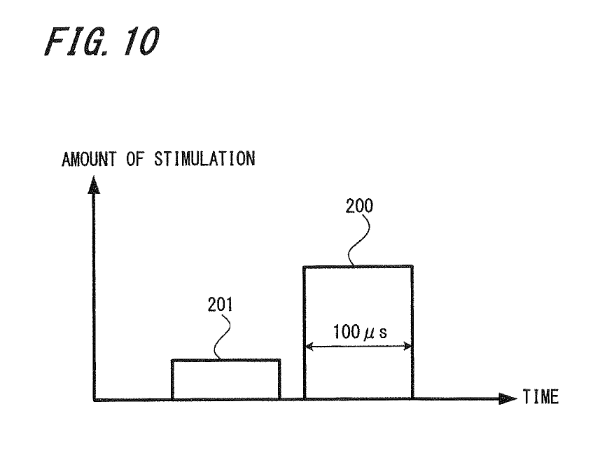

FIG. 8 shows an example of a plurality of pieces of adjustment data (an adjustment curve group) respectively corresponding to a plurality of stimulation intensities. Incidentally, FIG. 8 is a graph showing the correlation between the threshold ΔTth of the pulse width of the stimulation pulse and the skin impedance Z, where the horizontal axis represents the skin impedance, and the vertical axis represents the threshold of the pulse width of the stimulation pulse. Note that, in such example, the value of the stimulation current is constant for all pieces of adjustment data (adjustment curves). In other words, the adjustment curve group shown in FIG. 8 is an adjustment curve group of the stimulation intensity used when controlling the stimulation intensity with the pulse width of the stimulation pulse.

It is conventionally known that the relation between the threshold ΔTth of the pulse width of the stimulation pulse at the time when the user feels that the stimulation intensity is the same (i.e., the subjective stimulation intensity is constant) and the skin impedance Z is expressed by a curve (such curve is referred to as “equal loudness curve” hereinafter). Thus, in each of equal loudness curves 61 shown in FIG. 8, the same stimulation intensity can be obtained by the combination of threshold ΔTth of the pulse width of the stimulation pulse and the skin impedance Z on the same curve. Further, in FIG. 8, the farther the equal loudness curve 61 goes up within the equal loudness curve group 60, the stronger the stimulation intensity becomes.

Incidentally, since the equal loudness curve 61 is different for each user, the equal loudness curve 61 is not limited to the curve shown in FIG. 8. For example, depending on the user, the equal loudness curve may have linear characteristics.

To be specific, in this example, the adjustment of the amount of stimulation is performed as below. First, the adjustment data of the equal loudness curve group 60 is previously measured, wherein the equal loudness curve group 60 is formed by a plurality of equal loudness curves 61 respectively corresponding to various stimulation intensities. Further, the obtained adjustment data of the equal loudness curve group 60 is stored in the microprocessor 1.

Note that, the equal loudness curve group 60 can be created either by using the adjustment data measured for each user, or by using average adjustment data obtained based on the measurement previously performed for a plurality of subjects. Further, in the case where the stimulation current used when measuring the skin impedance Z is a constant value (like the case of the aforesaid embodiment), instead of the correlation data between the skin impedance Z and the threshold ΔTth of the pulse width of the stimulation pulse, correlation data between the voltage Vo of the end of the resistor 4 on the side of the switch group 14 and the threshold ΔTth of the pulse width of the stimulation pulse may also be used as the adjustment data.

Thereafter, the user selects an equal loudness curve 61 (stimulation intensity) corresponding to his (or her) favorite stimulation intensity from the equal loudness curve group 60 stored in the microprocessor 1. Incidentally, although not shown in FIG. 1, the selection operation of the user may be performed by using, for example, an operating section (i.e., such as buttons, switches, and/or the like: selecting section) arranged in the electrical stimulation device 10. Further, there is a possible configuration in which a force sensor is provided in the touch panel 15, the pressing force of the user is detected by the force sensor (selecting section), and the equal loudness curve 61 is automatically switched from one to another according to the detected pressing force.

Further, in the case where the skin is in touch with the electrode 30, the microprocessor 1 calculates, for each measurement cycle ΔTs of the skin impedance, the threshold ΔTth of the pulse width of the stimulation pulse from the selected equal loudness curve 61 (stimulation intensity) based on the measuring result of the skin impedance Z. Thereafter, the amount of stimulation is adjusted in the same manner as the aforesaid embodiment. With this example, it is possible to provide the user with optimum electrical stimulation stably in the aforesaid manner.

Since the device of this example is configured by further adding the stimulation intensity volume adjusting function to the electrical stimulation device 10 of the aforesaid embodiment, it is possible to perform stimulation adjustment according to the preference of the user. Thus, with this example, it is possible to provide an electrical stimulation device 10 that not only has the same advantages as the aforesaid embodiment, but also has better operability.

### [Modification 2]

The aforesaid embodiment is described based on an example in which the flowing stimulation current is constant in all period other than the final current-flowing period (i.e., the application period of the adjusting sub-pulse 42) of the stimulation pulse 40; however, the present invention is not limited to such example. The present invention includes a possible configuration in which the value of the stimulation current is suitably changed every time the skin impedance Z is measured, based on the measuring result. FIG. 9 shows an example (modification 2) of such configuration. FIG. 9 is a waveform diagram of a stimulation pulse 50 of the adjusting method of the amount of stimulation according to modification 2, wherein the horizontal axis represents the time, and the vertical axis represents the amount of stimulation (the current value).

As described above, with the electrical stimulation device 10 of the present embodiment, it is possible to perform the feedback processing with a processing time of about several us, and therefore, as shown in FIG. 9, it is sufficiently possible to perform control even if the value of the stimulation current is changed for each measurement cycle ΔTs of the skin impedance Z, based on the measuring result.

However, since the skin impedance Z changes along with the change of the stimulation current, when using this method, it is necessary to, for example, control current so that the relation between the skin impedance Z and the total amount of stimulation (amount of current) obtained by the stimulation pulse 50 becomes optimal. Thus, this method is somewhat complicated compared with the adjusting method described in the aforesaid embodiment.

### [Other Modifications]

The aforesaid embodiment is described based on an example in which, in order to increase the speed of the feedback control when performing stimulation adjustment, the D/A converter 2 and the A/D converter 3 each with a parallel interface are provided separately from the microprocessor 1; however, the present invention is not limited to such example. The present invention may include any configuration as long as the feedback control when performing the stimulation adjustment can be achieved in a processing time of about several us. For example, the present invention may include a configuration in which a D/A converter and an A/D converter each with a serial interface are used, as long as the D/A converter and A/D converter have performance that enables the aforesaid high-speed control.

The aforesaid embodiment is described based on an example in which the electrical stimulation device 10 is provided with a plurality of electrodes 30; however, the present invention is not limited to such example. The present invention may also be applied to an electrical stimulation device 10 that has only one electrode 30, and the same advantages can be achieved with such electrical stimulation device 10. However, in the electrical stimulation device 10 having only one electrode 30, since switching operation of the electrode 30 is not performed, the switch group 14 is not necessary.

The aforesaid embodiment is described based on a configuration example in which the changing-over switches 20 of the switch group 14 correspond one-to-one to the electrodes 30 of the touch panel 15; however, the present invention is not limited to such configuration example. The present invention may include a configuration in which each changing-over switch 20 is provided for a predetermined number of electrodes 30, according to, for example, intended use and/or the like.

Further, the aforesaid embodiment and modifications are described based on an example in which the information associated with the skin impedance Z measured (obtained) by the microprocessor 1 is skin impedance Z itself or the voltage Vo applied to the electrode 30; however, the present invention is not limited to such example. Any parameter can be used as the information associated with the skin impedance Z, as long as the parameter is a parameter associated with the skin impedance Z.

### [Various Applications]

The aforesaid embodiment is described based on an example in which the electrical stimulation device 10 is used alone;

however, the present invention is not limited to such example, the electrical stimulation device may be used as a module to be incorporated into various electronic devices and the like. For example, the electrical stimulation device of the present invention can be applied to various electronic devices such as a personal computer with touch panel function, a mobile device, a car navigation system with touch panel function, an information providing device for the visually impaired, and the like. Further, in addition to various electronic devices, the electrical stimulation device of the present invention may also be incorporated into machine components, such as the steering wheel of an automobile, touched by human skin.

In the case where the electrical stimulation device of the present invention is incorporated into the machine for the aforesaid use, the microprocessor 1 for providing tactile by electrical stimulation may either be provided separately from the main controller of the machine body, or be incorporated into the main controller of the machine body. However, as it stands now, since the main controller of the machine for the aforesaid use is not designed for the purpose of performing the feedback processing with a processing time of about several us, adequate processing speed can not be obtained. Thus, if the electrical stimulation device of the present invention is incorporated into the aforesaid machine, it is preferred that the microprocessor 1 for providing tactile by electrical stimulation is arranged separately from the main controller.

Further, in the case where a display for displaying information is provided in the machine body for the aforesaid use, an electrode is provided in the display arranged in the machine body so as to provide tactile providing function by the electrical stimulation. Incidentally, in the case of an electronic device having touch panel function, since electrodes are provided in the display panel (i.e., the display), the electrodes of the display panel may also serve as the electrodes for electrical stimulation.

In the case where the electrical stimulation device 10 of the present invention is applied to the aforesaid use, the information providing function performed by the display can be multifaceted.

1. An electrical stimulation device comprising:
an electrode adapted to provide electrical stimulation to a user;
an electrical signal supply section adapted to supply an electrical signal for generating the electrical stimulation to the electrode;
a skin impedance detection section adapted to detect information associated with skin impedance of the user; and
an electrical signal controller adapted to acquire, during the supply of the electrical signal, the information associated with the skin impedance through the skin impedance detection section in a cycle shorter than a supply period of the electrical signal, and adjust the electrical signal to be supplied to the electrode in the next cycle based on the acquired information associated with the skin impedance.

2. The electrical stimulation device according to claim 1, wherein the value of the electrical signal supplied by the electrical signal controller is constant in all current-flowing period other than the last cycle of the supply period of the electrical signal.

3. The electrical stimulation device according to claim 2, wherein the electrical signal controller stores correlation data that shows relationship between the threshold of the pulse width of an electrical pulse when the user starts to feel the electrical stimulation and the information associated with the skin impedance, calculates the threshold of the pulse width of the electrical pulse from the correlation data for each cycle based on the acquired information associated with the skin impedance, and compares the calculated threshold of the pulse width of the electrical pulse with the final supply period of the electrical signal obtained from an elapsed period from the start of the stimulation to the time when the information associated with the skin impedance is acquired, to thereby adjust the electrical signal to be supplied to the electrode in the next cycle.

4. The electrical stimulation device according to claim 3,
wherein the electrical signal controller has a plurality of pieces of the correlation data respectively corresponding to a plurality of stimulation intensities different from each other, and
wherein the electrical stimulation device further comprises a selecting section for the user to select a predetermined piece of correlation data from the plurality of pieces of correlation data.

5. The electrical stimulation device according to claim 1, wherein the electrical signal controller comprises:
a microprocessor adapted to acquire the information associated with the skin impedance for each cycle, and perform adjustment processing of the electrical signal based on the acquired information associated with the skin impedance;
a digital-to-analog converter adapted to convert a digital signal outputted from the microprocessor into an analog signal, and output the analog signal to the electrical signal supply section, wherein the interface of the digital-to-analog converter on the side of the microprocessor is a parallel interface; and
an analog-to-digital converter adapted to convert an analog signal outputted from the skin impedance detection section into a digital signal, and output the digital signal to the microprocessor, wherein the interface of the analog-to-digital converter on the side of the microprocessor is a parallel interface.

6. The electrical stimulation device according to claim 1, wherein the electrical signal supply section is a voltage-to-current converter that converts a voltage signal to a current signal.

7. The electrical stimulation device according to claim 1, further comprising:
a plurality of electrodes; and
a switch adapted to scan and select the plurality of electrodes in a predetermined order,
wherein the electrical signal controller controls the scanning and selecting processing of the switch, and supplies the electrical signal to the selected predetermined electrode.

8. The electrical stimulation device according to claim 1, wherein the information associated with the skin impedance is a voltage applied to the electrode.

9. The electrical stimulation device according to claim 1, wherein the electrical signal controller adjusts the supply period of the electrical signal based on the acquired information associated with the skin impedance.

10. The electrical stimulation device according to claim 1, wherein the electrical signal controller adjusts amount of current of the electrical signal for each the cycle based on the acquired information associated with the skin impedance.

11. An electrical stimulation method comprising the steps of:
supplying an stimulation current electrical signal to a predetermined electrode;
acquiring, during the supply of the stimulation current electrical signal, information associated with skin impedance of a user in a cycle shorter than one stimulation period supply period of the electrical signal of the predetermined electrode; and
adjusting the stimulation current electrical signal of the next cycle based on the acquired information associated with the skin impedance.
